(19) United States
(12) Patent Application Publication
(10) Pub. No.: US 2004/0075590 A1
(43) Pub. Date: Apr. 22, 2004

(54) E-learning biometric identification information system

(76) Inventor: Esther Mae Pearson, Groton, MA (US)

Correspondence Address: Esther M. Pearson, 15 Squannacook Drive, Groton, MA, 01450, US

(21) Appl. No.: 10/647,572

(22) Filed: Aug. 26, 2003

Related U.S. Application Data
(60) Provisional application No. 60/413,262, filed on Sep. 25, 2002.

(51) Int. Cl. H03M 11/00; H03K 17/94; G06F 7/04; H04Q 1/00

(52) U.S. Cl. 341/22; 340/5.83

(57) ABSTRACT

The “E-Learning Biometric Identification Information System” is an information systems technology invention. The “E-Learning Biometric Identification Information System” is both hardware and software. The hardware is a computer keyboard system that randomly based on a mathematical algorithm scans the users fingerprints as they press the keyboard keys. The scan of the fingerprints is then compared to stored fingerprints to determine and confirm the users true identity. The purpose of the “E-Learning Biometric Identification Information System” is to guard against online or distance learning student identification fraud during testing, evaluation or assessments.

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK

Appendix

### BACKGROUND OF THE INVENTION

This non-provisional Utility Patent Application is filed after submission of Provisional Patent Application No. 60/413,262. The invention combines two technologies. These technologies are e-Learning and Biometrics. The invention is an Information System relying on five components. These components are people, data, hardware, software, and networks. Related arts include Biometrics and e-Learning systems.

### BRIEF SUMMARY OF THE INVENTION

The E-Learning Biometric Identification Information System is an information system which uses Biometric fingerprint scans to detect a person's identity as the person partakes in an online test, evaluation or assessment. The E-Learning Biometric Identification Information System captures the fingerprint scan information and stores it, analyzes it and provides a report indicating the probability of a person's identity.

The fingerprint scans are captured based on random fingerprint scans captured using thirteen keyboard keys (including the lowercase letters a, b, c, d, e, f, i, n, o, r, s, t and x).

### BRIEF DESCRIPTION OF THE SEVERAL VIEWS OF THE DRAWING

List of Figures:

FIG. 1—E-Learning Biometric Identification Information System Overview Drawing

FIG. 2—E-Learning Biometric Identification Information System Process Flow

FIG. 3—E-Learning Biometric Identification Information System Keyboard with Left Hand Keys View

FIG. 4—E-Learning Biometric Identification Information System Keyboard with Right Hand Keys View

FIG. 5—E-Learning Biometric Identification Information System Key Sensor Drawing

FIG. 6—E-Learning Biometric Identification Information System Data Information Flow Chart

FIG. 7—EntrePad Fingerprint Sensor Bus Architecture by Authentec

### DESCRIPTION EXPLANATIONS OF THE FIGURES

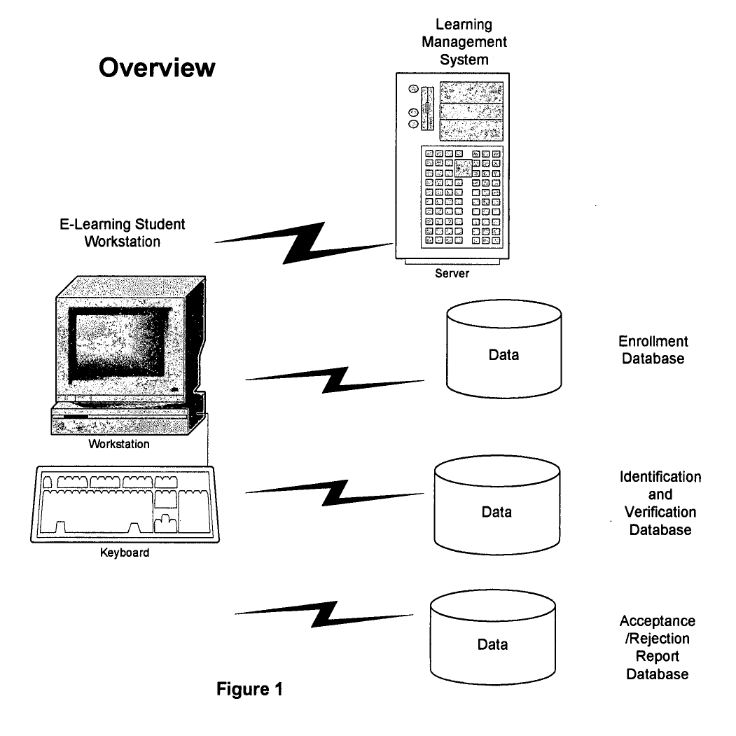

FIG. 1: E-Learning Biometric Identification Information System Overview Drawing—overview of major components of the E-Learning Biometric Identification System. FIG. 1 includes the keyboard system, Learning Management System (LMS), the database storage for biometric capture and storage of fingerprint scan data for user enrollment, identification, verification and reports for acceptance/rejection of user identification.

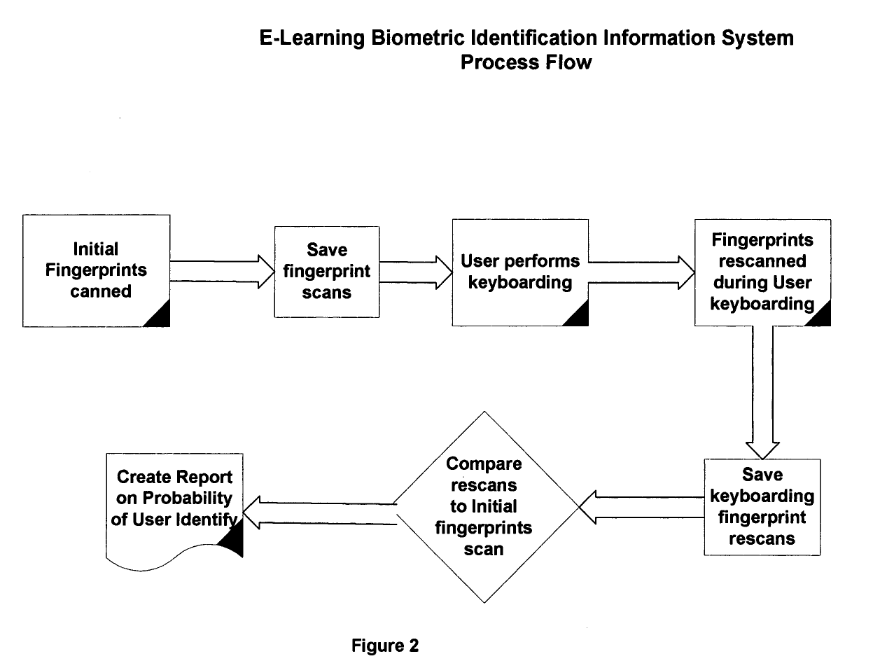

FIG. 2: E-Learning Biometric Identification Information System Process Flow—description of the process of user inputs and data flow.

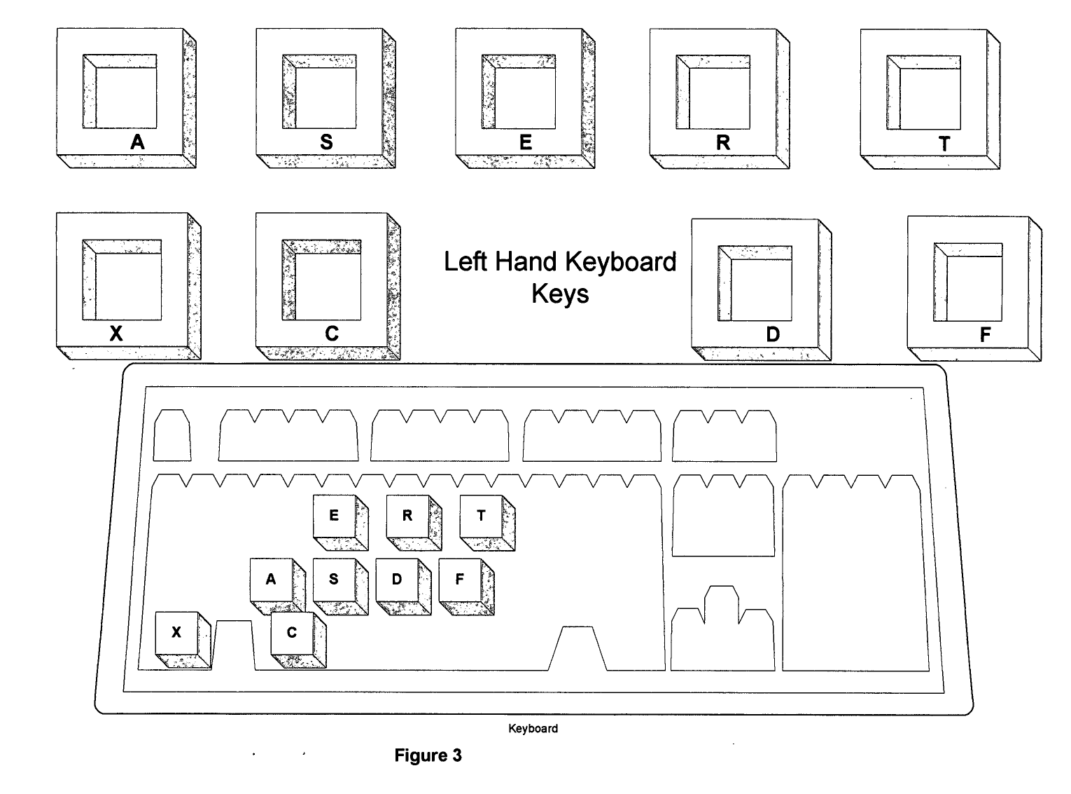

FIG. 3: E-Learning Biometric Identification Information System Keyboard with Left Hand Keys View—figure of the nine keyboard keys that are used by the left hand for typing common words, common base words, and test-type inputs. FIG. 3.0 indicates the keys have a clear top-front window to allow fingerprint chip to scan finger.

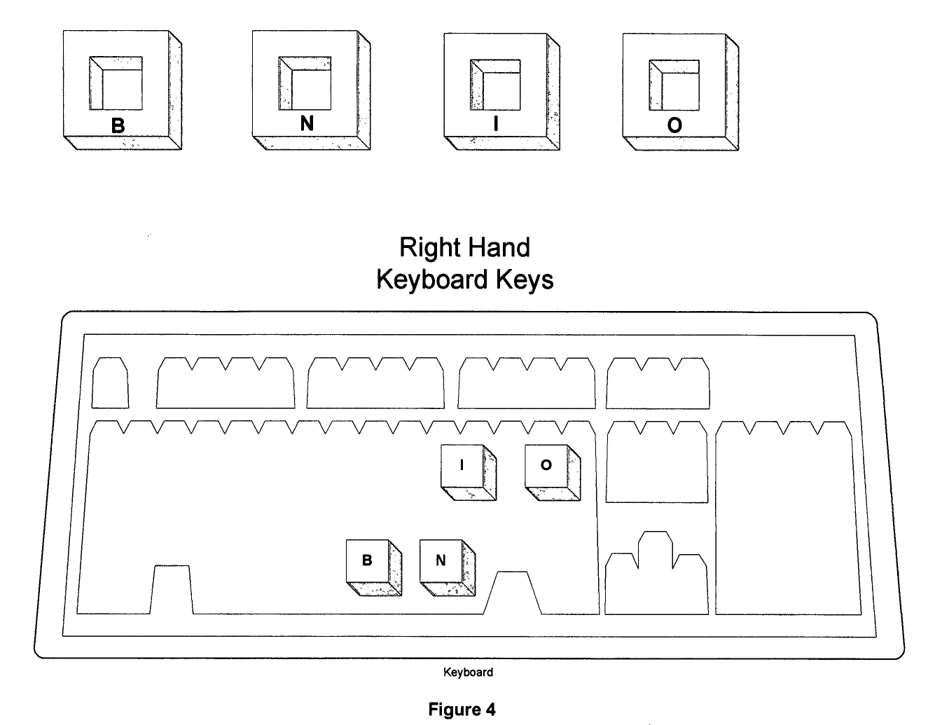

FIG. 4: E-Learning Biometric Identification Information System Keyboard with Right Hand Keys View—figure of the four keyboard keys that are used by the right hand for typing common words, common base words, and test-type inputs. FIG. 4.0 indicates the keys have a clear top-front window to allow fingerprint chip to scan finger.

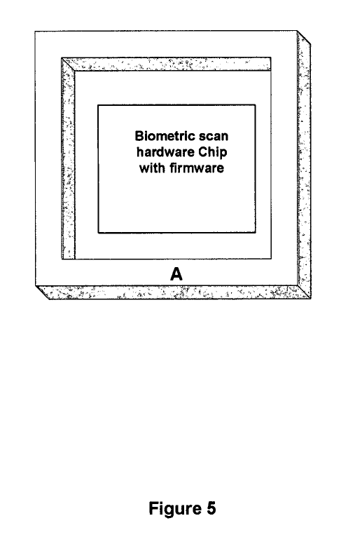

FIG. 5: E-Learning Biometric Identification Information System Key Sensor Drawing—cutaway figure of keyboard key showing the key with clear top-front window with EntrePad AES3500 Fingerprint Sensor chip/module in the interior of the key.

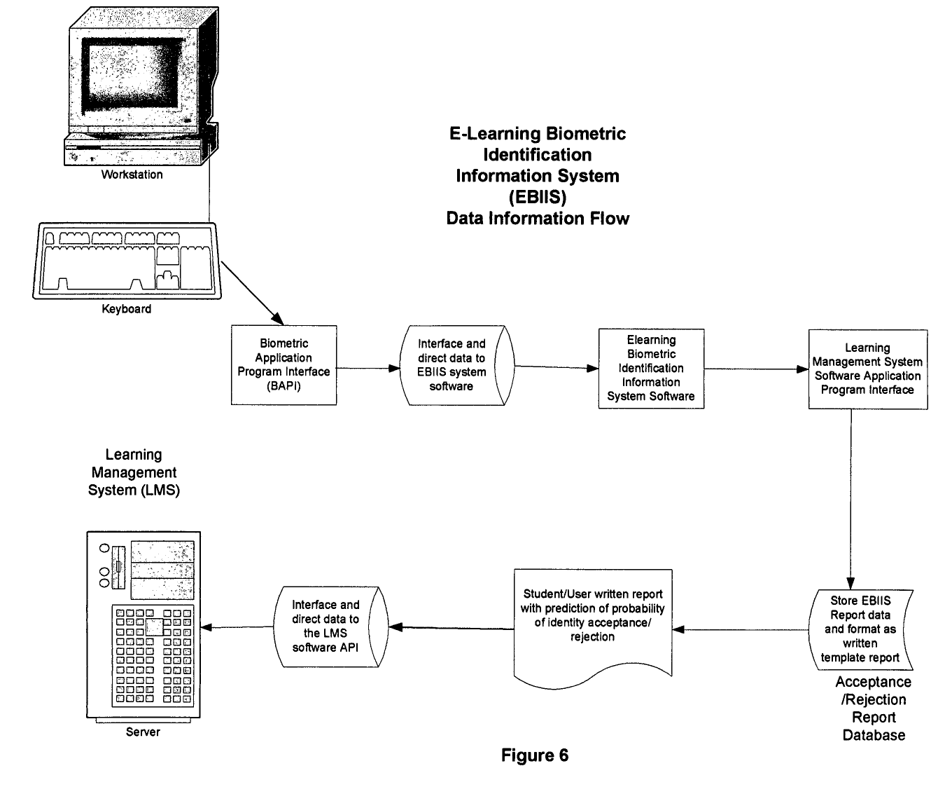

FIG. 6: E-Learning Biometric Identification Information System Data Information Flow Chart—demonstrates the flow of information from the computer keyboard to the Biometric System to the Learning Management System (LMS) and to the fingerprint scans databases for enrollment, identification, verification, and acceptance/rejection report databases.

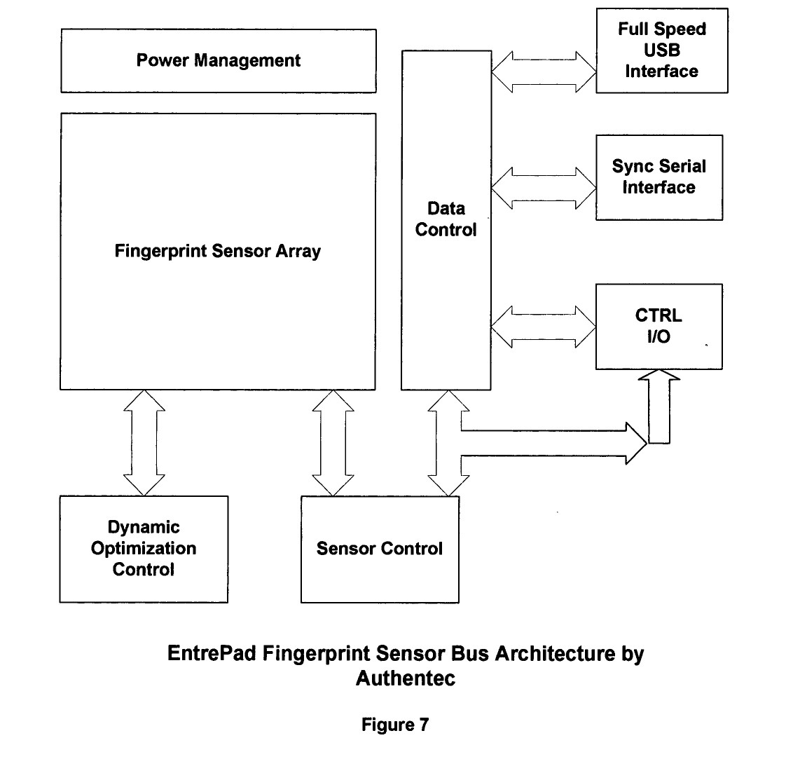

FIG. 7: EntrePad Fingerprint Sensor Bus Architecture by Authentec—figure of the internal flow of data in the fingerprint sensor information bus.

### DETAILED DESCRIPTION OF THE INVENTION

Manner and Process of Making:

The E-Learning Biometric Identification Information System specification or manner and process of making begin with manufacturing thirteen computer keyboard keys. The thirteen-computer keyboard keys makes up the E-Learning Biometric Identification Information System's input device. The keys are manufactured placing a transparent top covering on them and placing in their interior a Biometric fingerprint scan firmware device which scans the fingerprint and sends the scanned image to data storage. A software program then converts the fingerprint-scanned image into a mathematical identification. The mathematical identification is then stored as a signature of the fingerprint owner. This signature is used to compare future image scans to determine the identification of the keyboard user. The user includes a person taking an E-Learning course, in, whom an online test, evaluation or assessment is administered.

After the initial fingerprint scan, capture of the fingerprint image and mathematical identification storage, the keyboard rescans the users fingerprint on a random sampling period of time as the user is typing on the keyboard to complete an online test, evaluation or assessment. The sampling period for the rescan of users fingerprint is time and frequency tunable. Of the thirteen keys that are Biometric, the specific key that will perform the fingerprint rescan is random.

The rescans are then converted to a mathematical identification and the data stored. This stored data is then compared with the initial fingerprint scan signature. The comparison is performed by a software program, which also creates a report. The report states whether the rescan fingerprint data matches the signature fingerprint data. And a mathematical algorithm determines based on probability the likelihood of the identification of the user taking the test, evaluation, or assessment likelihood of being the true participant enrolled in the E-Learning course or an imposter.

When the user completes the online test, evaluation or assessment its answers, as well as, the “E-Learning Biometric Identification Information System” report is sent via Internet protocol transmission to the test, evaluation or assessment Administrator.

Technical Content:

The “E-Learning Biometric Identification Information System” is an education information system. The Information System is comprised of five components. These components are people, data, software, hardware and network resources. The purpose of the E-Learning Biometric Identification Information System is to provide a practical method for using Biometrics as a technology in the identification of e-learning participants wherein a high level of confidence is needed based on the criticality or high stakes decision-making based on the educational testing results.

The E-Learning Biometric Identification Information System captures and records the identification of an e-learning participant, stores this information in a database and makes this information available to virtual classroom administration through a report. The report provides a mathematical prediction of the statistical likelihood of the identity of the e-learning participant or individual. The E-Learning Biometric Identification Information System components include:

People—student participant or individual whose characteristics/attributes are sensed

Data—Biometric Enrollment data, Identification Mode data, Verification Mode data, Acceptance/Rejection data

Software—Learning Management System (LMS) Application Program Interface (API) for integration of Biometric program API's; and software for the Mathematical Prediction Algorithm for statistical reporting of individual's identity as confirmed as true or false

Hardware—Biometric sensor, and TPG customized Biometric keyboard keys

Network—Standard transmission IP protocols with Internet security encryption

Detailed descriptions of the components are as follows.

People

E-learning Student Participant or individuals engaged in test, assessment, or evaluation scenarios.

E-Learning Administrator concerned about identification of student participation or individual.

Data

Enrollment data obtained through a sensor (fingerprint(s) scan) observing an individuals characteristics/attributes, normalizing the observed data (giving it a mathematical signature), and storing the data in a biometric database.

Identification data obtained on a one-to-many basis, wherein the biometric system compares the given student or individual's characteristics/attributes with previously captured data, which identifies that given student or individual in comparison with other captured characteristics/attributes to determine match or non-match.

Verification data obtained on a one-to-one basis, wherein the biometric system compares the given student or individual's characteristics/attributes with previously captured data, which determines identity.

Acceptance/Rejection report data, which states whether statistically the student or individual's identity is confirmed as true or false based on identification and verification.

Software

Programs consist of the Learning Management System (LMS) which is the operating instructions in which the E-Learning curriculum, management, reporting, and communications is provided.

Programs consist of the Biometric observation operating instructions that control the sensing (fingerprint(s) scan) of the student or individuals characteristics/attributes, normalization of the attribute and transmitting of the normalized data to a Biometric database(s).

Programs consist of Biometric identification and verification mode data captured to provide comparison of the student or individuals characteristic/attribute with previously stored identification data available for participants.

Programs consist of the TPG operating instructions that control the sensor sampling algorithm and reporting of the acceptance/rejection of the students or individual's identity confirmation as true or false.

Program consists of the TPG report format, which captures acceptance/rejection data and reports it to E-Learning Administration personnel.

Hardware

Hardware consists of mechanical and electrical hardware sensors that observes characteristics/attributes data, and collects data for transmission to database(s).

Hardware consists of the computer system and peripherals (keyboard with biometric scanner keys).

Hardware consists of the sensor that observes, records and stores the one-to-one data for verification of a student or individual within a database of all stored scan data.

Network

Network consists of the transmission medium to transmit student participants or individuals normalized Biometric signature to the identification and verification database(s).

Network consists of the secure network connection that provides security and privacy of transmitted data over the Internet.

Network consists of the secure network connections and related data encryption models that provide secure data transmission.

Technical Operation:

Hardware:

The student participant or individual has 8 fingers scanned for enrollment of fingerprint characteristics/attributes. The fingers are scanned, not thumbs, for use in sensing during typing on the computer keyboard key while participating in completion of a test, evaluation, or assessment scenario.

The hardware consists of TPG customized keyboard “keys” (keys are lowercase a, b, c, d, e, f, i, n, o, r, s, t and x). These letters are the most frequently used letters in common words, base words and test answer types.

Software:

A software program related to the TPG customized keyboard, scan fingerprints at a TPG random pattern of sensing to capture rescans during student performance of evaluation, assessment or certification scenario. Randomly captured data is stored for identification and verification.

A software program analyzes data collected during random scanning of fingerprints to predict and report the acceptance/rejection of a student or individual's identity confirmation as true or false.

A software program with a mathematical algorithm to make statistical predictions taking into consideration the FAR (false acceptance rate—percentage of invalid student participants or individuals accepted) and FRR (false rejection rate—percentage of valid student participants or individuals wrongly rejected).

A software program, which uses statistics to determine the probability of a student or individual's identity based on fingerprint scan data.

A software program that queries the database that contains the student participant or individual's identity data. This data was obtained by the fingerprint random scans, which were stored in the database. The queries collect data, which is then formatted and encrypted for population of a report template.

The report template contains name, scan data verification from the random fingerprint scans, and a prediction of the probability of the true identification of the student participant or the individual identity.

Mathematical Algorithm(s):

A mathematical algorithm used to make statistical predictions of the probability of a student or individuals identity taking into consideration the FAR (false acceptance rate—percentage of invalid student participants or individuals accepted) and FRR (false rejection rate —percentage of valid student participants or individuals wrongly rejected).

1. What I claim as my invention is the E-Learning Biometric Identification Information System keyboard biometric sensor's layout and operation.

2. What I claim as my invention is the E-Learning Biometric Identification Information System keyboard keys, which contain built-in biometric fingerprint sensors.

3. What I claim as my invention is the E-Learning Biometric Identification Information System keyboard with most frequently used letters and common base word letters that include letters a, b, c, d, e, f, i, n, o, r, s, t and x keys selected to contain biometric fingerprint sensors.
